(19) United States
(12) Patent Application Publication
(10) Pub. No.: US 2012/0269018 A1
(43) Pub. Date: Oct. 25, 2012

(54) MEMORY SYSTEM HAVING MEMORY AND MEMORY CONTROLLER AND OPERATION METHOD THEREOF

(76) Inventors: Sang-Hoon SHIN, Gyeonggi-do (KR); Tae-Yong LEE, Gyeonggi-do (KR)

(21) Appl. No.: 13/315,074

(22) Filed: Dec. 8, 2011

(30) Foreign Application Priority Data
Apr. 25, 2011 (KR) 10-2011-0038528

(51) Int. Cl. G11C 29/04

(52) U.S. Cl. 365/200

(57) ABSTRACT

An operation method of a memory system including a memory and a memory controller includes transmitting defective-cell address information to the memory controller from the memory at an initial operation of the memory, wherein the defective-cell address information includes an address of a defective cell of the memory, and accessing, by the memory controller, an area of the memory excluding an area indicated by the defective-cell address information inside the memory.

### CROSS-REFERENCE TO RELATED APPLICATIONS

The present application claims priority of Korean Patent Application No. 10-2011-0038528, filed on Apr. 25, 2011, which is incorporated herein by reference in its entirety.

### BACKGROUND

1. Field

Exemplary embodiments of the present invention relate to a memory, a memory controller, and a memory system, and more particularly, to technology of handling fabrication defects in a memory.

2. Description of the Related Art

In the early stage of the semiconductor memory industry, a large number of original good dies (i.e., blocks of semiconducting materials) having no defective cell fabricated in a memory chip through a semiconductor fabrication process might be distributed over a semiconductor wafer. However, as the memory capacity increases, it becomes difficult to fabricate a memory chip having no defective cell. A method in which a spare memory, that is, a redundancy memory, is set to replace a defective cell is used to repair the defective cell. The conventional repair method includes the following processes: (1) determining where defective cells are positioned in a memory, through a test, (2) deriving a correct repair value by analyzing the number and positions of defective cells, and (3) replacing the defective cells with redundancy cells by programming a fuse circuit within the memory in response to the derived repair value. All of the processes (1), (2), and (3) may be performed by using a large number of test equipments and a lot of time. Therefore, the processes may increase the fabrication cost of the memory. Accordingly, a technology for reducing the number of equipments and time for handling the defective cells within the memory is useful.

### SUMMARY

An embodiment of the present invention is directed to technology of reducing a cost in handling defective cells by shortening a process of handling the defective cells.

In accordance with an embodiment of the present invention, an operation method of a memory system including a memory and a memory controller includes: transmitting defective-cell address information to the memory controller from the memory at an initial operation of the memory, wherein the defective-cell address information includes an address of a defective cell of the memory; and accessing, by the memory controller, an area of the memory excluding an area indicated by the defective-cell address information inside the memory.

In accordance with another embodiment of the present invention, a memory system includes: a memory including a plurality of data storage units configured to store data and a defective-cell address information storage unit configured to store defective-cell address information; and a memory controller configured to control the memory, receive the defective-cell address information from the memory, and read or write data from or into the data storage units of the memory excluding a unit indicated by the defective-cell address information among the plurality of data storage units.

In accordance with yet another embodiment of the present invention, an operation method of a memory controller includes: receiving defective-cell address information from a memory; storing the received defective-cell address information; and accessing an area of the memory to perform a read/write operation other than an area indicated by the defective-cell address information inside the memory.

In accordance with still another embodiment of the present invention, an operation method of a memory system including a memory and a memory controller includes: applying a test command to the memory from the memory controller; generating defective-cell address information by testing the memory in response to the test command; storing the defective-cell address information in the memory controller; and accessing, by the memory controller, an area of the memory excluding an area indicated by the defective-cell address information inside the memory.

In accordance with still another embodiment of the present invention, a memory controller includes: o a defect storage unit configured to store defective-cell address information of the memory; and a control unit configured to access an area of a memory excluding a data storage unit indicated by the defective-cell address information among a plurality of data storage units of the memory.

### BRIEF DESCRIPTION OF THE DRAWINGS

FIGS. 1 and 2 are diagrams illustrating an area where data are stored inside a memory.

FIG. 3 is a configuration diagram of a memory system in accordance with an embodiment of the present invention.

FIG. 4 is a flow chart showing an operation method of a memory system.

FIG. 5 is a flow chart showing an operation method of the memory system in accordance with another embodiment of the present invention.

FIG. 6 is a flow chart showing an operation method of the memory system in accordance with another embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

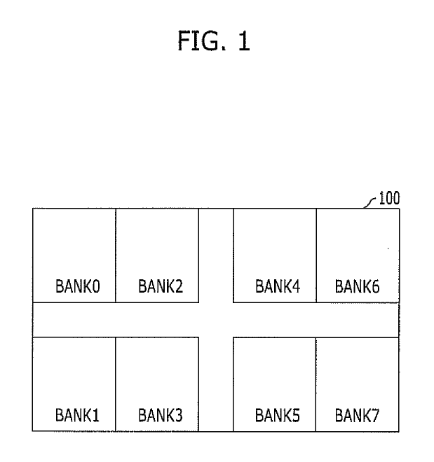

FIGS. 1 and 2 are diagrams illustrating an area where data are stored inside a memory 100.

Referring to FIG. 1, the memory 100 includes a plurality of memory banks BANK0 to BANK7. The number of memory banks may differ between memories. In general, one memory includes four, eight, or sixteen memory banks. FIG. 1 illustrates the memory having eight memory banks.

When the memory 100 includes eight memory banks BANK0 to BANK7 as illustrated in FIG. 1, each of the banks BANK0 to BANK7 may have a data capacity of 128 Mb.

FIG. 2 illustrates the memory bank BANK0 shown in FIG. 1. When the memory bank BANK0 having a data capacity of 128 Mb is divided into the units of 1 Mb, the memory bank BANK0 may include 128 1 Mb blocks as illustrated in FIG. 2.

Furthermore, one 1 Mb block may include four cell matrixes. Inside each of the cell matrixes, row lines called word lines and column lines called bit lines are provided, and memory cells store data under the control of the row lines and the column lines. FIG. 2 illustrates that one 1 Mb block includes four cell matrixes, and thus one cell matrix may have a data capacity of 256 kb. In this case, the cell matrix may be provided with 512 row lines and 512 column lines (512×512=256 k).

FIGS. 1 and 2 illustrate that the data storage places within the memory 100 have a structure with components (bank→block→cell matrix→memory cell). The structure and the numbers of the respective components may differ depending on the types and capacities of memories (for example, DDR2 SDRAM, DDR3 SDRAM, NAND-FLASH, and NOR-FLASH).

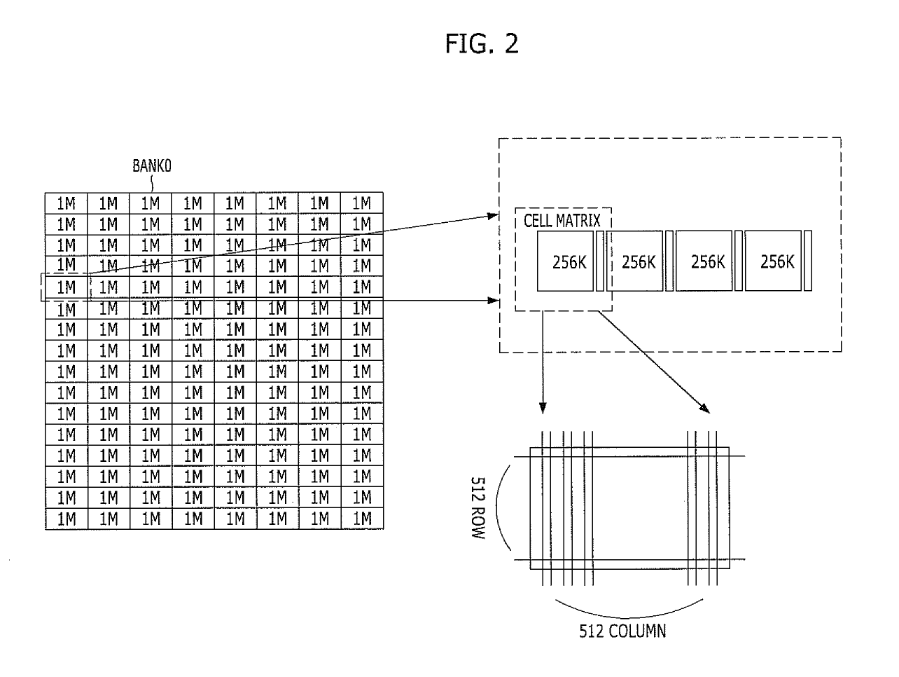

FIG. 3 is a configuration diagram of a memory system in accordance with an embodiment of the present invention.

Referring to FIG. 3, the memory system includes a memory 100 and a memory controller 110.

The memory 100 is an integrated circuit chip for storing data, and it may include DRAM, FLASH, PCRAM, and so on. All kinds of memories 100 store data and output the stored data under the control of the memory controller 110. The memory 100 includes a data storage area 101 which has the structure as described with reference to FIGS. 1 and 2 and in which data are stored, circuits for controlling the data storage area 101, and a defective-cell address information storage unit 102 for storing defective-cell address information. The circuits are not illustrated in FIG. 3.

Between the memory 100 and the memory controller 110, a data channel DATA CHANNEL through which data is transmitted, a command channel CMD CHANNEL through which a command is transmitted, and an address channel ADD CHANNEL through which an address is transmitted are provided. Depending on memory systems, the channels may be integrated with each other or separated from each other. FIG. 3 illustrates the data channel DATA CHANNEL, the command channel CMD CHANNEL, and the address channel ADD CHANNEL are separated from each other.

The memory controller 110 includes a control logic 111 having one or more circuits for controlling the memory 100 and a defective-cell address information storage unit 112 for storing defective-cell address information to be described below.

In accordance with the embodiment of the present invention, the memory 100 is tested to detect a defect address, i.e. an address of a defective cell, after the memory 100 is fabricated, but may not be repaired based on the test result. That is, among the processes described in the conventional repair method: (1) determining where defective cells are positioned in a memory, through a test, (2) deriving a repair value by analyzing the number and positions of the defective cells, and (3) replacing the defective cells with redundancy cells by programming a fuse circuit within the memory in response to the derived repair value, only the process (1) is performed, and the other processes (2) and (3) may not be performed. Furthermore, the defect address detected through the process (1) is stored in the defective-cell address information storage unit 102 within the memory 100. Hereafter, how the memory may operate properly without the processes (2) and (3) is described.

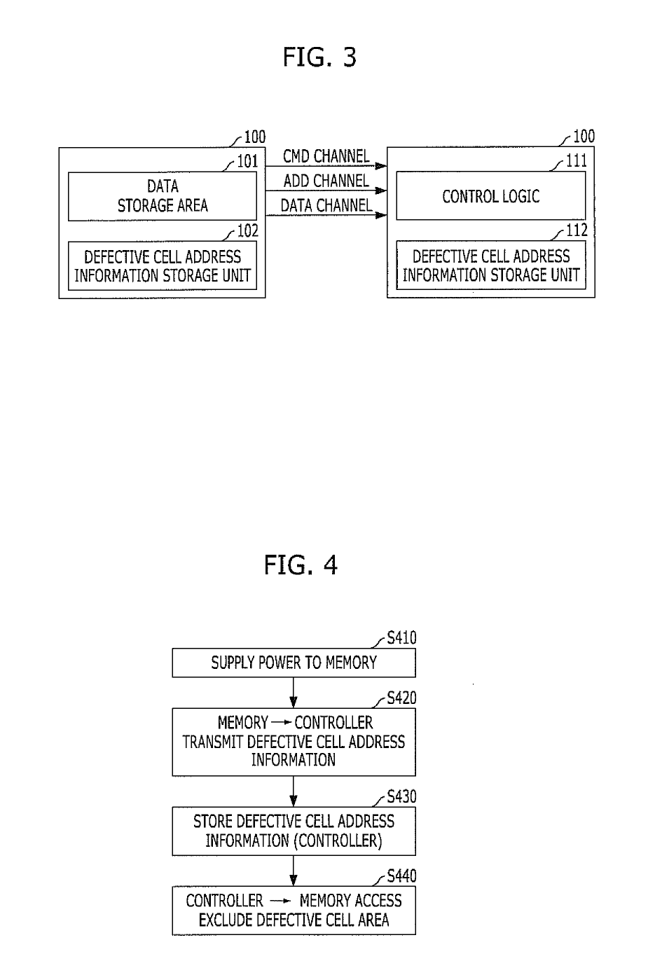

FIG. 4 is a flow chart showing an operation method of a memory system.

The operation method of FIG. 4 may be performed when the positions of defective cells inside the memory 100 are determined through a test of the memory 100 after the memory 100 is fabricated, and the defect address is stored in the defective-cell address information storage unit 102 inside the memory 100 as the determination result.

Referring to FIG. 4, power is supplied to the memory 100 at step S410. After the power is supplied to the memory 100, defective-cell address information is transmitted to the memory controller 110 from the memory 100 at step S420. Since the performance of the step S420 is to be preceded to properly operate the memory system, the step S420 may be performed at an initialization operation of the memory 100. The transmission of the defective-cell address information from the memory 100 to the memory controller 110 may be performed through the channels such as the data channel DATA CHANNEL, the command channel CMD CHANNEL, and the address channel ADD CHANNEL, which are provided between the memory 100 and the memory controller 110. Furthermore, a defective-cell address information channel (not illustrated) for transmitting the defective-cell address information may be separately provided between the memory 100 and the memory controller 110, and the defective-cell address information may be transmitted through the defective-cell address information channel.

When the defective-cell address information is transmitted from the memory 100 to the memory controller 110, the memory controller 110 stores the transmitted defective-cell address information in the defective-cell address information storage unit 112 at step S430. Then, the memory controller 110 accesses the memory 100 to perform a read/write operation. In this embodiment of the present invention, the memory controller 100 does not access/use the entire storage area of the memory 100, but accesses the memory 100 excluding an area indicated by the defective-cell address information inside the memory 100, at step S440. Therefore, since data is not read from or written into a defect memory cell inside the memory 100, malfunction may be prevented from occurring in the operation of the memory system.

Conventionally, when defect memory cells were found in the memory 100, the defect memory cells were replaced with redundancy cells (repair) and then the redundancy cells were used. In accordance with the embodiment of the present invention, however, when defect memory cells are found in the memory 100, address information of the defect memory cells is transmitted to the memory controller 110, and the defect memory cells are excluded when the memory controller 110 accesses the memory 100 to perform a read/write operation, in order to deal with the defects of the memory 100.

The defective-cell address information may stored by a variety of units. For example, the defective-cell address information may be stored by the unit of bank, the unit of memory block, the unit of cell matrix, or the unit of row and column inside the cell matrix. Tables 1 to 4 below represent the defective-cell address information.

TABLE 1
Defective-cell address information

Bank 1, Bank 3, Bank 6 Defect

According to Table 1, the defective-cell address information is written by the unit of bank. Table 1 shows that the banks 1, 3, and 6 have a defect. Therefore, the memory controller 110 accesses only the other banks excluding the banks 1, 3, and 6 among the banks 0 to 7 of the memory 100.

TABLE 2
Defective-cell address information

| | |
|---|---|
| Bank 0 | No Defect |
| Bank 1 | Block 0, 24, 36 Defect |
| Bank 2 | No Defect |
| Bank 3 | Block 1, 70, 100 Defect |
| Bank 4 | No Defect |
| Bank 5 | No Defect |
| Bank 6 | Block 30, 66 Defect |
| Bank 7 | No Defect |

According to Table 2, the defective-cell address information is written by the unit of block inside a bank. According to Table 2, the memory controller 110 accesses all blocks inside a bank when accessing the banks 0, 2, 4, 5, and 7, accesses all blocks excluding the blocks 0, 24, and 36 when accessing the bank 1, accesses all blocks excluding the blocks 1, 70, and 100 when accessing the bank 3, and accesses all blocks excluding the blocks 30 and 66 when accessing the bank 6. When the defective-cell address information is stored as shown in Table 2, the size of the defective-cell address information increases in comparison with Table 1, but the access prohibition area inside the memory 100 is reduced. That is, as the defective-cell address information is stored in more detail, the area where the access is prohibited in the memory 100, that is, an area which may not be used is reduced.

TABLE 3
Defective-cell address information

| | |
|---|---|
| Bank 0 | No Defect |

| | | |
|---|---|---|
| Bank 1 | Block 0 | Cell matrix 1 Defect |
| | Block 24 | Cell matrix 0 Defect |
| | Block 36 | Cell matrix 3 Defect |

| | |
|---|---|
| Bank 2 | No Defect |

| | | |
|---|---|---|
| Bank 3 | Block 1 | Cell matrix 2 Defect |
| | Block 70 | Cell matrix 0 Defect |
| | Block 100 | Cell matrix 0 Defect |

| | |
|---|---|
| Bank 4 | No Defect |
| Bank 5 | No Defect |

| | | |
|---|---|---|
| Bank 6 | Block 30 | Cell matrix 1 Defect |
| | Block 66 | Cell matrix 3 Defect |

| | |
|---|---|
| Bank 7 | No fail |

According to Table 3, the defective-cell address information is stored by the unit of cell matrix inside a block. When the defective-cell address information is stored as shown in Table 3, the size of the defective-cell address information increases in comparison with Table 2, but the area where the access is prohibited due to a defect in the memory 100 is reduced in comparison with Table 2.

TABLE 4
Defect address information

| Bank 0 | No Defect | | |
|---|---|---|---|
| Bank 1 | Block 0 | Cell matrix 1 | Row 300, column 218 Defect |
| | Block 24 | Cell matrix 0 | Row 56 Defect |
| | Block 36 | Cell matrix 3 | Column 100, column 138 Defect |
| Bank 2 | No fail | | |
| Bank 3 | Block 1 | Cell matrix 2 | Row 34 Defect |
| | Block 70 | Cell matrix 0 | Column 478 Defect |
| | Block 100 | Cell matrix 0 | Row 10, column 38 Defect |
| Bank 4 | No Defect | | |
| Bank 5 | No Defect | | |
| Bank 6 | Block 30 | Cell matrix 1 | Row 23, column 489 Defect |
| | Block 66 | Cell matrix 3 | Column 230, column 410 Defect |

| | |
|---|---|
| Bank 7 | No Defect |

According to Table 4, the defective-cell address information is stored by the unit of row and column inside a cell matrix. Since Table 4 includes the largest amount of information among Tables 1 to 4, the size of the defective-cell address information is the largest, but the area where the access is prohibited due to a defect inside the memory 100 is the smallest.

As shown in Tables 1 to 4, the defective-cell address information may be stored in the variety of units. When the defective-cell address information is stored by a large unit, the size of the defective-cell address information decreases, but the area where the access is prohibited inside the memory 100 increases. On the other hand, when the defective-cell address information is stored by a small unit, the size of the defective-cell address information increases, but the area where the access is prohibited inside the memory 100 may be minimized.

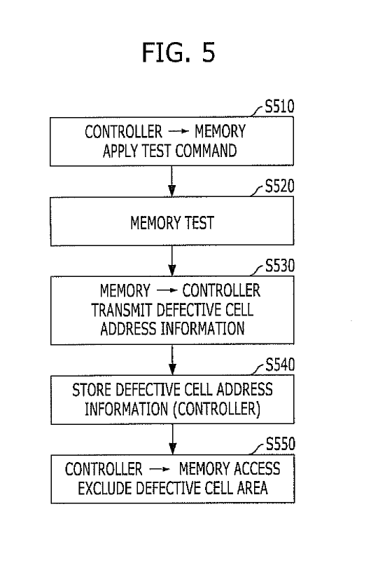

FIG. 5 is a flow chart showing an operation method of the memory system in accordance with another embodiment of the present invention.

The operation method of FIG. 5 may be performed when the memory 100 includes a test circuit (not illustrated) capable of detecting defective cells. Such a circuit is generally known as a built-in self test circuit.

Referring to FIG. 5, a test command is applied to the memory 100 from the memory controller 110 at step S510. The test circuit inside the memory 100 tests the data storage area 101 inside the memory 100 in response to the applied test command. As the test result, defective-cell address information is generated at step S520. The defective-cell address information may be represented in various manners as shown in Tables 1 to 4. The defective-cell address information generated through the test circuit of the memory 100 is transmitted to the memory controller 110 at step S530. The transmission of the defective-cell address information may be performed through the channels such as the data channel DATA CHANNEL, the command channel CMD CHANNEL, and the address channel ADD CHANNEL, which are provided between the memory 100 and the memory controller 110. Furthermore, a defective-cell address information channel for transmitting the defective-cell address information may be separately provided between the memory 100 and the memory controller 110, and the defective-cell address information may be transmitted through the defective-cell address information channel.

When the defective-cell address information is transmitted to the memory controller 110 from the memory 100, the memory controller 110 stores the transmitted defective-cell address information in the defective-cell address information storage unit 112 at step S540. Then, the memory controller 110 accesses the memory 100 to perform a read/write operation. In this case, the memory controller 110 accesses the memory 100 excluding the area indicated by the defective-cell address information inside the memory 100, at step S550.

The steps S510 to S530 may be periodically repeated to provide against a defect which newly occurs during the operation of the memory 100. For example, the steps S510 to S530 may be performed once a week or whenever the number of read/write operations performed approaches a predetermined number or more, and the information on the new defect may be updated into the defective-cell address information.

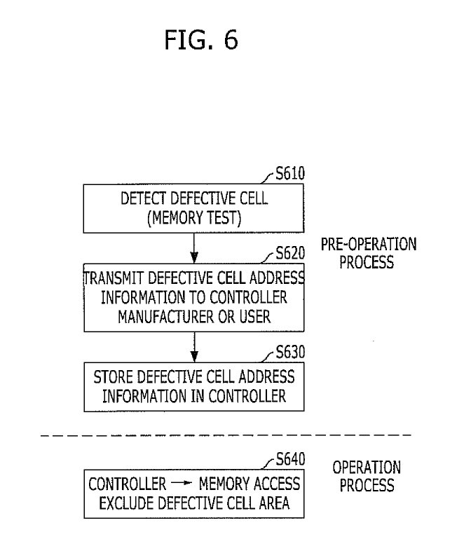

FIG. 6 is a flow chart showing an operation method of the memory system in accordance with another embodiment of the present invention.

FIG. 6 shows a case that defective-cell address information of the memory 110 is stored in the defect storage unit 112 of the memory controller 110, before the operation of the memory system. For example, the defect address of the memory 100 is detected through a test in manufacturing the memory 100, and the detected information may be stored in the memory controller 110 when manufacturing the memory controller 110, i.e., before operating the memory system.

Referring to FIG. 6, defective cells inside the memory 100 are detected through a test in fabricating the memory 100 and the defective-cell address information is generated as the detection result, at step S610. The defective-cell address information is transmitted to the manufacturer or user of the memory controller 110 at step S620, and the manufacturer of the memory controller 110 writes the defective-cell address information into the memory controller 110, or the user writes the defective-cell address information into the memory controller 110 at step S640.

Furthermore, during the operation of the memory system, the memory controller 110 accesses the memory 100 excluding the area indicated by the defective-cell address information inside the memory 100, based on the stored defective-cell address information, at step S650.

In the embodiments of the present invention, it is described that the memory controller communicates with one memory. However, the embodiments of the present invention may also be applied to a case that a memory controller communicates with a plurality of memories. When the memory controller communicates with a plurality of memories, the defective-cell address information of each memory and a unique ID of the memory may be stored in the memory controller.

In accordance with the embodiments of the present invention, since the memory controller accesses the area of the memory excluding the defect area, an available storage capacity may be reduced. However, the reduction may be covered by an agreement between a memory manufacturer and users, which allows how much the storage capacity is reduced. For example, an agreement to allow that a memory capacity is reduced by 10% may be made between the memory manufacturer and the users.

In accordance with the embodiments of the present invention, the defective-cell address information is stored in the memory controller, and the memory controller accesses the area excluding the defect area when accessing the memory. Therefore, the memory may be operated without being repaired.

Therefore, the process of deriving a repair value and repairing the memory in response to the repair value may be omitted during the fabrication of the memory, and the fabrication cost of the memory may be reduced.

While the present invention has been described with respect to the specific embodiments, it will be apparent to those skilled in the art that various changes and modifications may be made without departing from the spirit and scope of the invention as defined in the following claims.

What is claimed is:

1. An operation method of a memory system including a memory and a memory controller, comprising:
transmitting defective-cell address information to the memory controller from the memory at an initial operation of the memory, wherein the defective-cell address information includes an address of a defective cell of the memory; and
accessing, by the memory controller, an area of the memory excluding an area indicated by the defective-cell address information inside the memory.

2. The operation method of claim 1, wherein the accessing of the memory comprises:
writing data into the area of the memory excluding the area indicated by the defective-cell address information; and
reading the written data.

3. The operation method of claim 1, wherein the defective-cell address information is transmitted through a data channel through which data is transmitted between the memory and the memory controller.

4. The operation method of claim 1, wherein the defective-cell address information is transmitted through a separately provided information channel.

5. A memory system comprising:
a memory comprising a plurality of data storage units configured to store data and a defective-cell address information storage unit configured to store defective-cell address information; and
a memory controller configured to control the memory, receive the defective-cell address information from the memory, and read or write data from or into the data storage units of the memory excluding a unit indicated by the defective-cell address information among the plurality of data storage units.

6. The memory system of claim 5, wherein the data storage units comprise memory banks of the memory, memory blocks of a memory bank, a row of memory cells of a memory block, or a column of memory cells of a memory block.

7. The memory system of claim 6, wherein the defective-cell address information is stored by one or more memory banks, memory blocks, or row or column of memory cells inside a memory block.

8. The memory system of claim 5, wherein the defective-cell address information storage unit comprises a plurality of fuse circuits.

9. The memory system of claim 5, further comprising:
a data channel, an address channel, and a command channel between the memory and the memory controller,
wherein the defective-cell address information is transmitted through one or more of the channels.

10. The memory system of claim 5, further comprising:
a defective-cell address information channel between the memory and the memory controller,
wherein the defective-cell address information is transmitted through the defective-cell address information channel.

11. The method system of claim 5, wherein the memory controller is configured to receive the defective-cell address information from the memory during an initialization operation of the memory and store the received defective-cell address information.

12. The method system of claim 5, further comprising:
a plurality of memory devices as the memory,
wherein the memory controller is configured to receive and store the defective-cell address information with identification information for one of the memory devices.

13. An operation method of a memory controller, comprising:
receiving defective-cell address information from a memory;
storing the received defective-cell address information; and
accessing an area of the memory to perform a read/write operation other than an area indicated by the defective-cell address information inside the memory.

14. The operation method of claim 13, wherein the receiving of the defective-cell address information and the storing of the received defective-cell address information are performed at an initialization operation of the memory.

15. An operation method of a memory system including a memory and a memory controller, comprising:
applying a test command to the memory from the memory controller;
generating defective-cell address information by testing the memory in response to the test command;
storing the defective-cell address information in the memory controller; and
accessing, by the memory controller, an area of the memory excluding an area indicated by the defective-cell address information inside the memory.

16. The operation method of claim 15, wherein the applying of the test command, the generating of the defective-cell address information, and the storing of the defective-cell address information are periodically repeated.

17. A memory controller comprising:
a defect storage unit configured to store defective-cell address information of the memory; and
a control unit configured to access an area of the memory excluding a data storage unit indicated by the defective-cell address information among a plurality of data storage units of the memory.

18. The memory controller of claim 17, wherein the defective-cell address information is stored in the defect storage unit, before the operation of the memory controller starts.
